(19) United States
(12) Patent Application Publication
(10) Pub. No.: US 2013/0075607 A1
(43) Pub. Date: Mar. 28, 2013

(54) IMAGE SENSORS HAVING STACKED PHOTODETECTOR ARRAYS

(71) Applicants: MANOJ BIKUMANDLA, San Jose, CA (US); Dominic Massetti, San Jose, CA (US)

(72) Inventors: MANOJ BIKUMANDLA, San Jose, CA (US); Dominic Massetti, San Jose, CA (US)

(21) Appl. No.: 13/241,032

(22) Filed: Sep. 22, 2011

(51) Int. Cl. H01L 27/146; H01L 31/18

(52) U.S. Cl. 250/332; 250/208.1; 438/65; 257/E31.127

(57) ABSTRACT

An image sensor of an aspect includes a first photodetector array and a second photodetector array. The second photodetector array is coupled under the first photodetector array. Photodetectors of the second photodetector array are coupled under corresponding photodetectors of the first photodetector array. The image sensor includes a thickness of a photocarrier generation material optically coupled between the corresponding photodetectors of the first and second arrays. Other image sensors, methods of making the image sensors, methods of using the image sensors, and color filter patterns for such image sensors are also disclosed.

### BACKGROUND

1. Field

Embodiments relate to the field of image sensors. In particular, embodiments relate to an image sensor having a first photodetector array and a second photodetector array coupled under the first photodetector array.

2. Background Information

Image sensors are prevalent. The image sensors may be used in a wide variety of applications, such as, for example, digital still cameras, cellular phones, digital camera phones, security cameras, optical mice, as well as various other medical, automobile, military, or other applications.

FIG. 1 is a cross-sectional side view of a prior art frontside illuminated (FSI) pixel 100 for an FSI image sensor. For simplicity, a single pixel is shown, although typically there will be a two-dimensional array of such pixels. The pixel includes a substrate 101, an interconnect portion 107 over the substrate, a color filter 108 over the interconnect portion, and a microlens 109 over the color filter. The substrate 101 has a frontside 105 and a backside 106. The frontside is the side of the substrate over which the interconnect portion 107 is disposed.

A photodiode 102, pixel circuitry 103, and shallow trench isolation (STI) 104, are disposed within a frontside portion of the substrate 101. The interconnect portion 107 is used to convey signals to and from the pixel circuitry 103. The illustrated interconnect portion includes three insulating or dielectric layers within which two metal layers (labeled M1 and M2) are disposed. The metal layers represent metal lines, traces, or other interconnects. The metal layers or interconnects are generally patterned or arranged in order to form an opening or optical passage through which light 110, which is provided from the frontside 105, may reach the photodiode 102.

FIG. 2 illustrates a Bayer filter pattern 212 of different color filters 208. One of the different color filters 208 may be used for the color filter 108 of FIG. 1. The different color filters 208 include a first green color filter 208G1, a second green color filter 208G2, a blue filter 208B, and a red color filter 208R. The green filters may substantially block penetration of all light except for green light (e.g., transmit green light through them), the blue filter may substantially block penetration of all light except for blue light, and the red filter may substantially block penetration of all light except for red light. Each of the different color filters may correspond to a different pixel of an image sensor. For example, first green color filter 208G1 may correspond to a first pixel and the red color filter 208R may correspond to a second, neighboring pixel. Typically, each laterally adjacent pixel in the image sensor is to sense only one of the image colors (e.g., only one of red, green, or blue).

Referring again to FIG. 1, a portion of the light 110 that is able to pass through the color filter 108 may be transmitted through the dielectric layers of the interconnect portion 107 and into a material (e.g., a silicon or other semiconductor material) of the substrate 101. The light may penetrate into the material of the substrate to a depth that is based on the wavelength of the light before generating the charge carriers. Provided that the material has sufficient thickness, at least some of the light may tend to free charge carriers in the material. As shown, photogenerated charge carriers, such as electrons (e-), may be generated or freed in the material, such as a semiconductor material.

FIG. 3 illustrates that the depth at which electrons or other charge carriers are generated as a result of light 310 transmitted through a semiconductor material 301 depends upon the wavelength of the light. For example, the depth of penetration prior to photocarrier generation tends to increase with increasing wavelength of the light. Different wavelengths of light have different colors in the visible spectrum. Light of relatively shorter wavelengths, such as blue light 213 and green light 214, tends to penetrate less deeply than light of relatively longer wavelengths of light, such as red light 215, and especially near infrared light 216 and infrared light 217. By way of example, the depth of penetration of blue and green light in silicon is generally contained within about 2 micrometers (μm), whereas the depth of penetration of red light generally extends beyond 2 μm. Accordingly, in order to detect longer wavelengths of light, such as red light, and especially near infrared light and infrared light, a greater thickness of the material is needed to generate the charge carriers.

However, using a greater thickness of the material to generate the charge carriers may tend to pose various challenges. For one thing, using a greater thickness of material for photogeneration of charge carriers may tend to increase the amount of electrical crosstalk. In order to be detected, the electrons (e-) or other charge carriers should move from their point of generation within a given pixel toward the photodetector of that same pixel. However, in electrical crosstalk the electrons (e-) or other charge carriers may migrate or move from their point of generation within a given pixel away from the photodetector of that pixel and into a neighboring pixel. Instead of being detected by the photodetector of the pixel within which the electrons were generated, the electrons may be detected by the photodetector of the neighboring pixel. Such electrical crosstalk may tend to blur images, or otherwise reduce image quality, and is generally undesirable.

Electrons generated farther from the photodetector (e.g., deeper within the material of the substrate) tend to be more prone to such electrical crosstalk as compared to electrons generated closer to the photodetector (e.g., shallower within the material). For example, there may be a farther distance for the electrons to travel and/or there may be less isolation for the photodiodes at increased thicknesses. Consequently, more electrical crosstalk may be encountered when a greater thickness of the material used for the photogeneration of charge carriers is used to detect light of higher wavelengths, such as, red light, and especially near infrared and infrared lights. Increased blooming, reduced mean transfer function, and other factors may also occur when a greater thickness of the material used for the photogeneration of charge carriers is used to detect light of higher wavelengths.

### BRIEF DESCRIPTION OF THE SEVERAL VIEWS OF THE DRAWINGS

The invention may best be understood by referring to the following description and accompanying drawings that are used to illustrate embodiments of the invention. In the drawings:

FIG. 1 is a cross-sectional side view of a prior art frontside illuminated (FSI) pixel for an FSI image sensor.

FIG. 2 illustrates a prior art Bayer filter pattern.

FIG. 3 illustrates that the depth at which electrons or other charge carriers are generated as a result of light transmitted through a semiconductor material depends upon the wavelength of the light.

FIG. 4 is a cross-sectional schematic diagram of an example embodiment of an image sensor.

FIG. 5 is a block flow diagram of an example embodiment of a method of making an image sensor.

FIG. 6 is a cross-sectional schematic diagram of an example embodiment of an image sensor including an FSI image sensor coupled over a BSI image sensor.

FIGS. 7A-7I are cross-sectional side views of intermediate assemblies representing different stages of an example embodiment of a method of forming an example embodiment of an image sensor that includes an FSI image sensor coupled over a BSI image sensor.

FIG. 8A is a block diagram of a first example embodiment of a color filter pattern.

FIG. 8B is a block diagram of a second example embodiment of a color filter pattern.

FIG. 9 is a block diagram of an example embodiment of an image sensor system.

### DETAILED DESCRIPTION

In the following description, numerous specific details are set forth. However, it is understood that embodiments of the invention may be practiced without these specific details. In other instances, well-known circuits, structures and techniques have not been shown in detail in order not to obscure the understanding of this description.

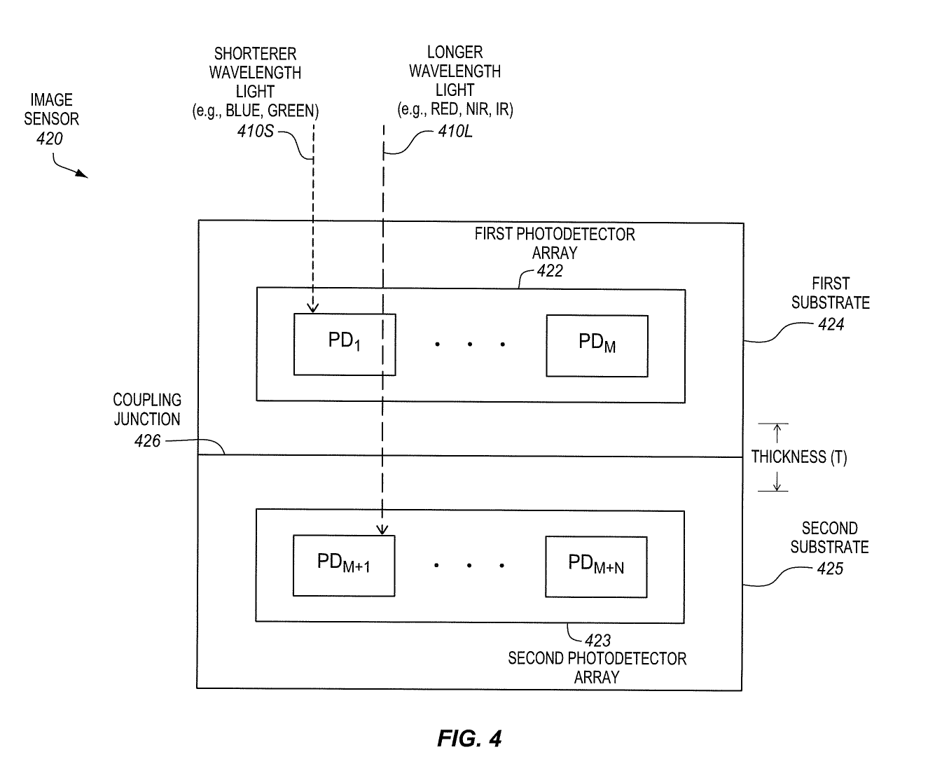

FIG. 4 is a cross-sectional schematic diagram of an example embodiment of an image sensor 420. The image sensor includes a first photodetector array 422 and a second photodetector array 423. The first and second photodetector arrays are coupled with one another. As shown, a major image sensing surface (e.g., a plane of the array) of one of the photodetector arrays is coupled vertically under a major image sensing surface of the other, although it is to be appreciated that the image sensor may be used in various different orientations (e.g., an inverted orientation or an orientation where the image sensor is turned sideways). In the illustrated embodiment, the major image sensing surface of the second photodetector array is coupled vertically under the major image sensing surface of the first photodetector array.

In some embodiments, the first photodetector array 422 may be formed or disposed within a first substrate 424 and the second photodetector array 423 may be formed or disposed within a second substrate 425. As used herein, a photodetector array “formed or disposed within a substrate” encompasses a photodetector array formed or disposed in the substrate, a photodetector array formed or disposed over the substrate, or a photodetector array formed or disposed partly in and partly over the substrate. The first and second substrates may be bonded, adhered, or otherwise physically coupled together at a junction or interface 426. In such embodiments, the first and second photodetector arrays are fabricated or formed on separate wafers or other substrates (i.e., as opposed to both being fabricated monolithically on one single substrate), and then the separate wafers or other substrates are coupled together.

A few representative examples of approaches for coupling the substrates include, but are not limited to, using an adhesive (e.g., glue, glass frit, or other organic or inorganic adhesive material), reactive bonding, thermo-compression bonding, direct wafer bonding, and using other substrate-substrate bonding (e.g., wafer bonding) approaches. In some embodiments, an additional material (e.g., an adhesive) may be included between the substrates in order to hold them together, whereas in other embodiments no such additional material may be used. In some aspects, each of the substrates may be a die or other semiconductor substrate. The die or other semiconductor substrate may include predominantly semiconductor material, but may also include other non-semiconductor materials, such as, for example, dielectrics, metals, and organic insulator materials.

The first photodetector array 422 includes a first photodetector (PD₁) and an Mth photodetector (PD_{M}). The second photodetector array 423 includes an (M+1)th photodetector (PD_{M+1}) and an (M+N)th photodetector (PD_{M-N}). M and N are integers of any desired size, which may be equal, but are not required to be equal. Often, N and M may each be in the millions, in order to provide an image sensor with a resolution in megapixels, although the scope of the invention is not so limited. The photodetectors of the second photodetector array are coupled under corresponding photodetectors of the first photodetector array. For example, as shown in the illustrated image sensor, the (M+1)th photodetector (PD_{M+1}) is coupled under the first photodetector (PD₁) and the (M+N)-th photodetector (PD_{M+N}) is coupled under the Mth photodetector (PD_{M}). It is not required that each photodetector of one of the arrays have a corresponding photodetector in the other array. For example, in some embodiments, one of the arrays (e.g., the upper array) may provide a higher resolution.

Representative examples of suitable photodetectors include, but are not limited to, photodiodes, charge-coupled devices (CCDs), quantum device optical detectors, photogates, phototransistors, and photoconductors. In some embodiments, the photodetectors may be of the type used in complementary metal-oxide-semiconductor (CMOS) active-pixel sensors (APS). In some embodiments, the photodetectors may be photodiodes. Representative examples of suitable photodiodes include, but are not limited to, P-N photodiodes, PIN photodiodes, and avalanche photodiodes. In some embodiments, P-N photodiodes and other types of photodiodes used in CMOS APS are used.

The image sensor includes a thickness (T) of a photocarrier generation material that is optically coupled between the corresponding pairs of photodetectors of the first and second arrays (e.g., between PD₁ and PD_{M+1}). The photocarrier generation material is operable to generate photocarriers, such as photogenerated electrons or holes. In some embodiments, the photocarrier generation material may include predominantly silicon or another semiconductor material, although dielectrics and other materials may also optionally be included. The first photodetector array 422 is a relatively shallow photodetector array that is separated from incoming light 410S, 410L by a relatively lesser thickness of photocarrier generation material, whereas the second photodetector array 423 is a relatively deeper photodetector array that is separated from the incoming light 410S, 410L by a relatively greater thickness of photocarrier generation material that includes the thickness (T).

In some embodiments, the thickness (T) of the photocarrier generation material may help to allow the photodetectors of the second photodetector array 423 to be operable to detect a different portion of the input light than a portion of the input light that the photodetectors of the first photodetector array 422 are operable to detect. For example, in some embodiments, the photodetectors of the second photodetector array may be operable to detect relatively longer wavelength light 410L (without detecting relatively shorter wavelength light 410S), whereas the photodetectors of the first photodetector array may be operable to detect relatively shorter wavelength light 410S (without detecting relatively longer wavelength light 410L). As shown, the relatively longer wavelength light 410L may penetrate through the thickness (T) of the photocarrier generation material prior to being detected by the photodetectors of the second deeper photodetector array, but the relatively shorter wavelength light 410S may not penetrate through the thickness (T).

The thickness (T) of the photocarrier generation material between the corresponding pairs of photodetectors may provide additional photocarrier generation thickness for the relatively longer wavelength light 410L to travel. This may allow the photodetectors of the second photodetector array to detect relatively longer wavelength light by providing a greater thickness of material in which the light may be converted to photogenerated electrons. The thickness (T) of the photocarrier generation material also helps to block, optically filter out, or otherwise prevent the relatively shorter wavelength light 410S from reaching the photodetectors of the second photodetector array. That is, the photocarrier generation material (e.g., silicon or semiconductor) itself may serve as a color filter based on the wavelength-dependent absorption of light. By way of example, about 1.0-1.5 μm of silicon may be sufficient to absorb a majority of green and shorter wavelengths of light such that the remaining light may be of a longer wavelength than green light (e.g., red light and wavelengths greater than red light), so that these longer wavelengths may be detected by the lower photodetectors.

In various embodiments, the thickness (T) of the silicon or other photocarrier generation material between the corresponding pairs of photodetectors of the first and second arrays may be at least 0.5 μm, at least 1 μm, at least 1.5 μm, at least 2 μm, at least 5 μm, or even thicker, depending upon the split of wavelengths desired to be detected by the first photodetector array as compared to those of the second photodetector array for the particular implementation. The thickness (T) of the photocarrier generation material may be provided by the first substrate 424, the second substrate 425, or a combination of the first and second substrates. In the illustration, part of the thickness (T) is provided by the first substrate and part of the thickness (T) is provided by the second substrate.

In one example embodiment, all of the photodetectors of the first photodetector array 422 may be operable to detect relatively shorter wavelength visible light 410S having wavelengths that are less than those of red light (e.g., wavelengths less than about 605 nm), and all of the photodetectors of the second photodetector array 423 may be operable to detect relatively longer wavelength light 410L having wavelengths that are equal to and greater than that of the red light (e.g., wavelengths equal to and greater than about 605 nm). Red light has wavelengths centered at about 620-750 nm but a red pixel may also include some orange light having wavelengths centered at about 590-620 nm. In various aspects, the photodetectors of the second photodetector array may also be operable to detect at least some near infrared light, substantially all near infrared light, substantially all near infrared light plus at least some infrared light, and substantially all near infrared light plus most of infrared light. Near infrared light has wavelengths between about 750-1400 nm and infrared light has wavelengths between about 1400-300000 nm.

In another example embodiment, all of the photodetectors of the first photodetector array 422 may be operable to detect relatively shorter wavelength visible light 410S having wavelengths that are less than those of near infrared light (e.g., wavelengths less than about 750 nm), and all of the photodetectors of the second photodetector array 423 may be operable to detect relatively longer wavelength visible light 410L having wavelengths that are equal to and greater than that of the near infrared light (e.g., wavelengths equal to and greater than about 750 nm). In various aspects, the photodetectors of the second photodetector array may also be operable to detect substantially all near infrared light, substantially all near infrared light plus at least some infrared light, and substantially all near infrared light plus most of infrared light. These are just a few examples, and other splits of other wavelengths or colors between the photodetectors of the first and second photodetector arrays are also contemplated.

Advantageously, the example embodiment of the image sensor 420 provides stacked photodetector arrays that are coupled over one another with a thickness (T) of a photocarrier generation material optically coupled between the stacked photodetector arrays. The photodiodes of the corresponding pairs are stacked one over the other, which helps to provide for high pixel densities and avoid needing to provide larger areas to accommodate the photodiodes, which may otherwise be the case if they were provided adjacent one another in the horizontal dimension or plane of the substrate, as opposed to being vertically stacked. The corresponding pairs of photodiodes (e.g., PD₁ and PD_{M+1}) may form combined photodiodes with two different but coordinated readouts.

One of the photodiodes may detect a first portion of the visible and/or non-visible spectrum for an image (e.g., near infrared or infrared), while the other photodiode may detect a second, different portion of the visible and/or non-visible spectrum for the image. For example, the photodetector of a pair closer to the input light may be operable to detect relatively shorter wavelength light (e.g., blue and green light), while the photodetector of the pair farther from the input light may be operable to detect relatively longer wavelength light (e.g., red and near infrared light) with the relatively shorter wavelength light optically filtered or blocked out by the thickness (T).

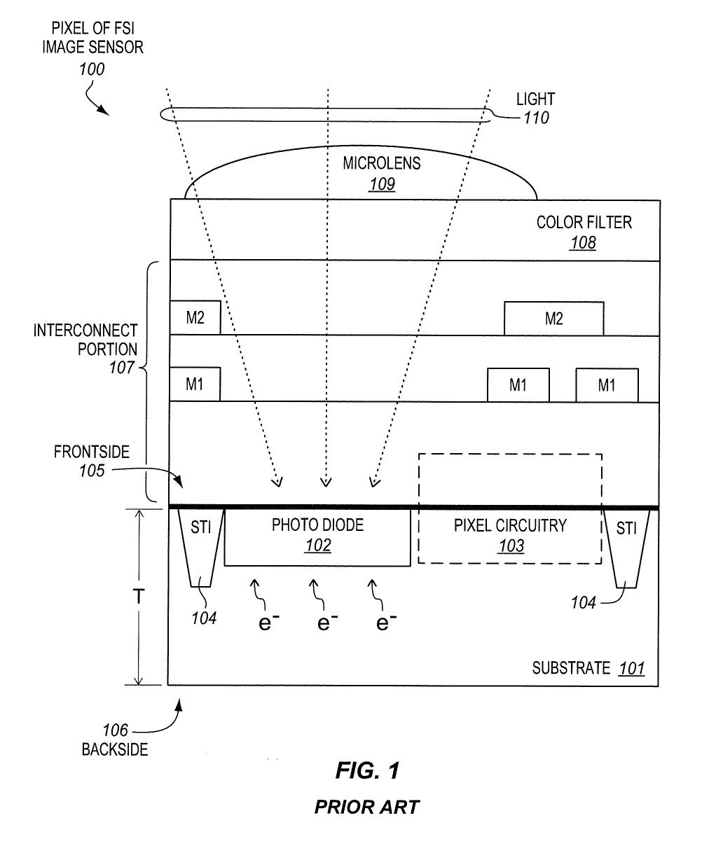

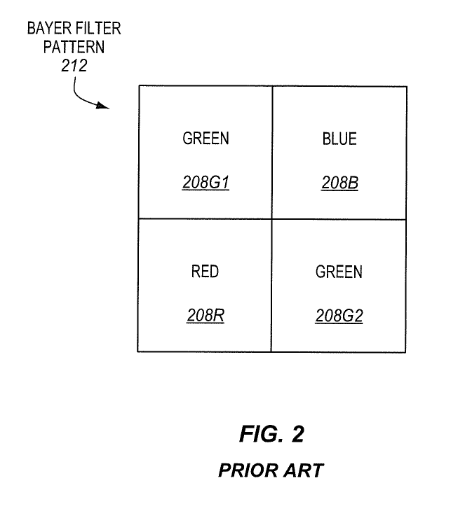

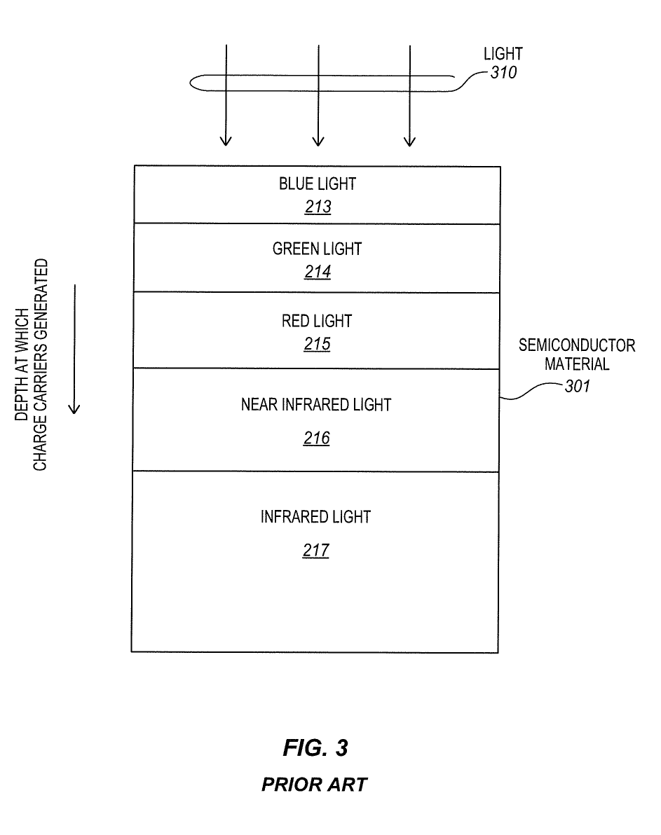

Advantageously, the photodetectors, and especially the photodetectors of the second photodetector array, may be operable to detect the light with reduced levels of crosstalk (e.g., electrical crosstalk and optical crosstalk) and blooming, with increased mean transfer function, etc. The reduced crosstalk may be due to various aspects. For one thing, the electrons or charge carriers generated from the relatively longer wavelength light may be generated relatively closer to the corresponding photodetector or collection region of the second photodetector array, as compared to what would be the case for the prior art approach shown in FIG. 1, which may result in less opportunity for the charge carriers to travel to an adjacent pixel's photodiode. Moreover, shallow trench isolation (STI) or other isolation (not shown), between the adjacent pixels, may extend across a greater proportion of the vertical thickness of the first and/or second substrates, which may help to reduce both optical and electrical crosstalk. Further, optical crosstalk may be reduced, for example, by reducing the amount of light that may be reflected off of the bottom of the first substrate into an adjacent pixel where it may generate carriers.

As mentioned above, in some embodiments, the image sensor 420 may be used to detect at least some near infrared light and/or at least some infrared light. This may be useful in various applications. The near infrared and/or infrared light may represent the temperature and/or heat of the objects being imaged. The near infrared and/or infrared light may also be available at times when the amount of visible spectrum light is limited (e.g., at night or in dark locations). Night vision cameras, security cameras, surveillance cameras, and the like may detect near infrared and/or infrared light to generate thermal, heat, or temperature images and/or to image in dark locations. Cameras on cars, trucks, and other motorized vehicles may detect near infrared and/or infrared light to generate thermal, heat, or temperature images and/or image in dark locations for navigation and/or the detection of nearby objects. Moreover, the near infrared and/or infrared light may allow imaging or detection of objects that are concealed by fog, clouds, mist, or the like. Cameras for target acquisition, homing, tracking, and the like, may similarly benefit from being able to detect near infrared and/or infrared light. In still other embodiments, endoscopes and other medical devices may also benefit from being able to detect at least some near infrared and/or infrared light in order to detect inflammation, heat emitting substances or locations, etc. Image sensors as disclosed herein may be included in such devices and used for such applications, as well as others that will be apparent to those skilled in the art and having the benefit of the present disclosure. The image sensors used for such embodiments may help to reduce the amount of electrical crosstalk, blooming, and the like when detecting the near infrared and/or infrared light.

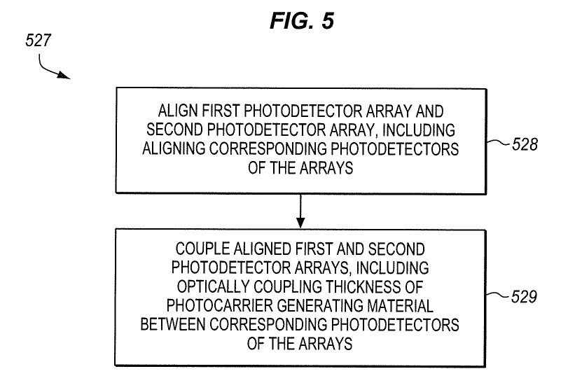

FIG. 5 is a block flow diagram of an example embodiment of a method 527 of making an image sensor. The method may be used to make an image sensor either the same as, similar to, or entirely different than the image sensor 420 of FIG. 4. Moreover, the image sensor 420 of FIG. 4 may be made by a method either the same as, similar to, or entirely different than the method of FIG. 5.

The method includes aligning a first photodetector array and a second photodetector array, at block 528. The aligning the first and second photodetector arrays may include aligning photodetectors of the second photodetector array and corresponding photodetectors of the first photodetector array.

The method includes coupling the aligned first and second photodetector arrays, at block 529. In one aspect, this may include coupling a first wafer or other semiconductor substrate in which the first photodetector array is formed with a second wafer or other semiconductor substrate in which the second photodetector array is formed. In some embodiments, the substrates may be coupled with at least one of an adhesive, a glue, reactive bonding, thermo-compression bonding, and wafer bonding. The coupling may include optically coupling a thickness of a photoelectron or other photocarrier generation material between the aligned corresponding photodetectors of the first and second photodetector arrays.

In some embodiments, an image sensor as disclosed herein may include a frontside illuminated (FSI) image sensor or FSI photodetector array coupled with a backside illuminated (BSI) image sensor or BSI photodetector array. As previously mentioned, an FSI photodetector array or FSI image sensor is illuminated from the frontside, which is the side of the substrate on which the interconnect portion is disposed. In the FSI image sensor, the interconnect portion is optically disposed between a light source (e.g., a microlens arranged to receive backscattered light from an object being imaged) and the FSI photodetector array. The interconnect portion is closer to the light source than the FSI photodetector array. The light is transmitted through the interconnect portion prior to reaching the FSI photodetector array. In contrast, a BSI photodetector array or BSI image sensor is illuminated from the backside, which is the side of the substrate opposite that on which the interconnect portion is disposed. In the BSI image sensor, the interconnect portion is farther from the light source than the BSI photodetector array. The light encounters the BSI photodetector array portion prior to reaching the interconnect portion.

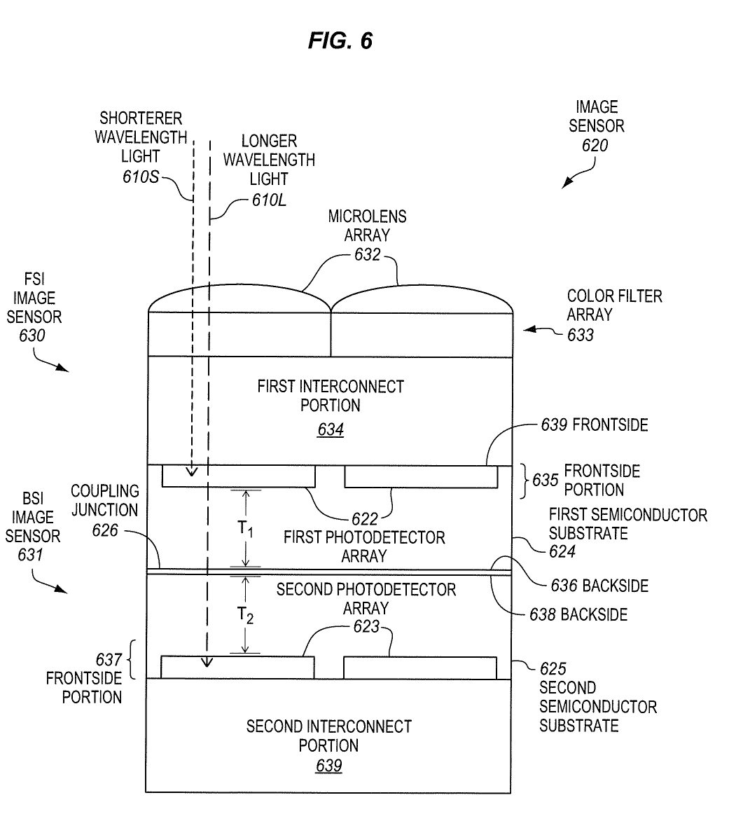

FIG. 6 is a cross-sectional schematic diagram of an example embodiment of an image sensor 620 including an FSI image sensor 630 coupled over a BSI image sensor 631. For simplicity, two pixels are shown, although typically the image sensor may include a two dimensional array with a multitude of pixels. The FSI image sensor includes a microlens array 632. During operation, the microlens array is operable to receive and focus incoming light 610S, 610L (e.g., backscattered light from an object being imaged). A color filter array 633 of the FSI image sensor is optically coupled to receive the focused light from the microlens array and operable to filter the light. A first interconnect portion 634 of the FSI image sensor is optically coupled to receive the light from the color filter array. The first interconnect portion may include interconnects (not shown) such as lines, wires, traces, vias, etc. disposed within a dielectric material (not shown). The interconnects may be arranged to provide windows to the photodetectors through which light may pass. The dielectric material may be operable to transmit the light.

The FSI image sensor also includes a first die or other semiconductor substrate 624. The first die is optically coupled to receive the light from the dielectric material. The first die includes a first array of photodetectors 622 disposed within a frontside portion 635 of the first die. The first array of photodetectors is operable to detect a first shorter wavelength portion 610S of the light received by the first die. The first die also includes a first thickness (T1) of a semiconductor material coupled between the first array of photodetectors and a backside 636 of the first die. The first thickness (T1) of the semiconductor material is operable to transmit a second longer wavelength portion 610L of the light, which has not been detected by the first array of photodetectors. In some embodiments, the backside 636 of the FSI image sensor 630 is a thinned backside that has been thinned by an amount (e.g., from around 200 μm initially to around 1-20 μm) appropriate to provide the desired split of color detection by the corresponding pairs of photodetectors.

The BSI image sensor 631 is coupled under the FSI image sensor 630 at a coupling junction 626. The BSI image sensor includes a second die or other semiconductor substrate 625. The second die is optically coupled to receive the second longer wavelength portion 610L of the light that has not been detected by the first array of photodetectors. The second die includes a second array of photodetectors 623 disposed within a frontside portion 637 of the second die. The second die also includes a second thickness (T2) of a semiconductor material coupled between the second array of photodetectors and a backside 638 of the second die. The second thickness (T2) of the semiconductor material is operable to transmit the second longer wavelength portion 610L of the light. The second array of photodetectors is operable to detect the second portion of the light. The BSI image sensor also includes a second interconnect portion 639 coupled with the frontside portion of the second die.

In one embodiment, all of the photodetectors of the FSI photodetector array or FSI image sensor may be operable to detect visible light having relatively lower wavelengths (e.g., blue and green light), and all of the photodetectors of the BSI photodetector array or BSI image sensor may be operable to detect light having relatively higher wavelengths (e.g., equal to and potentially greater than that of the red light). The blue light may have wavelengths centered at about 450-475 nm and the green light may have wavelengths centered at about 495-570 nm. In various aspects, the photodetectors of the BSI photodetector array or BSI image sensor may also be operable to detect at least some near infrared light, substantially all near infrared light, substantially all near infrared light plus at least some infrared light, and substantially all near infrared light plus most of infrared light.

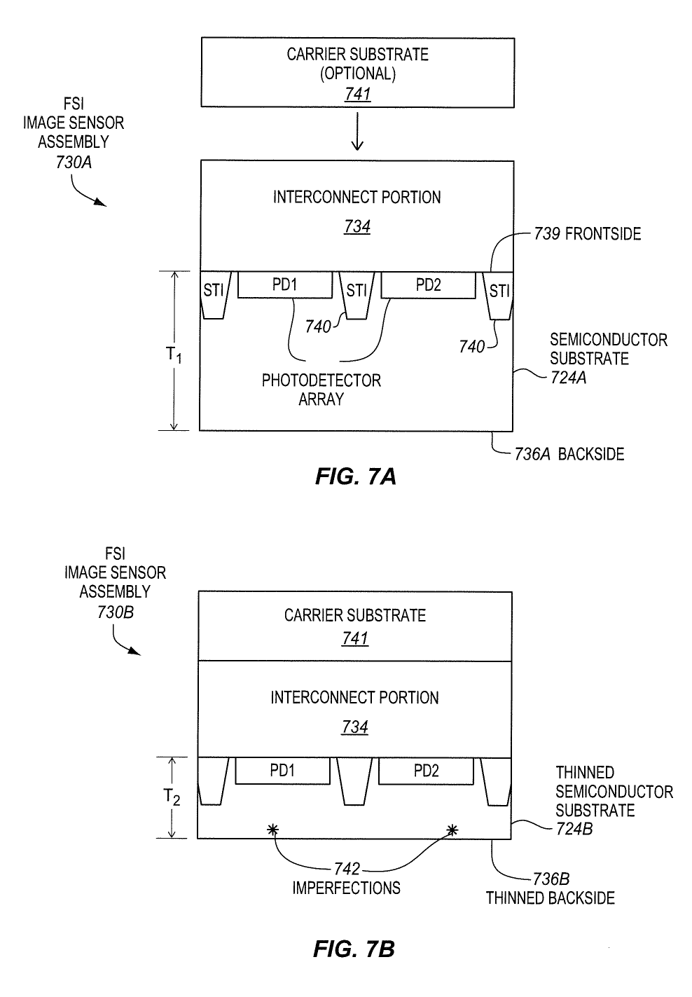

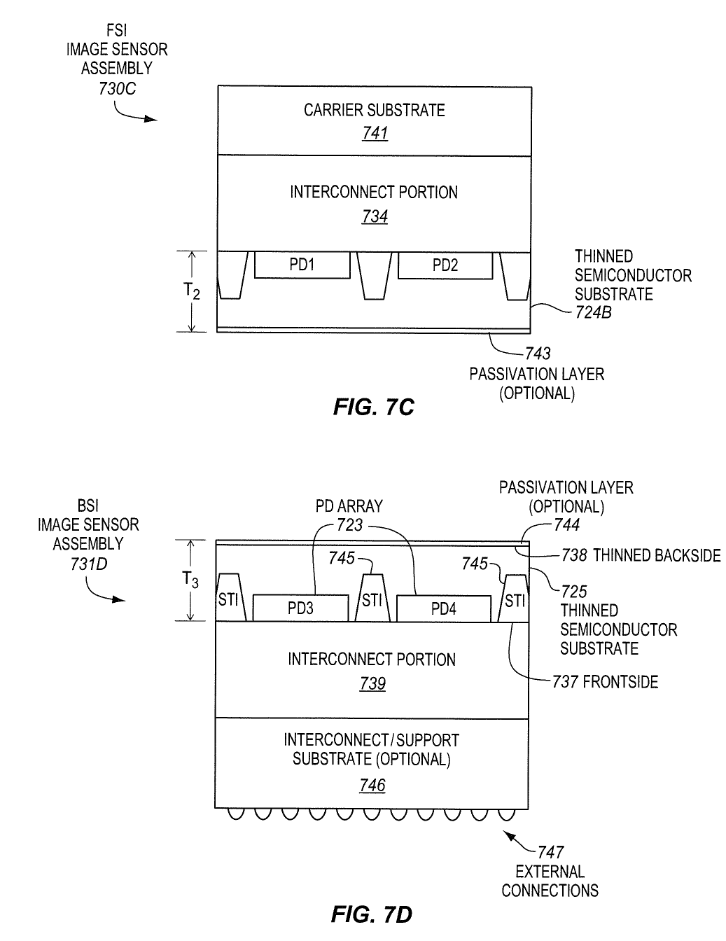

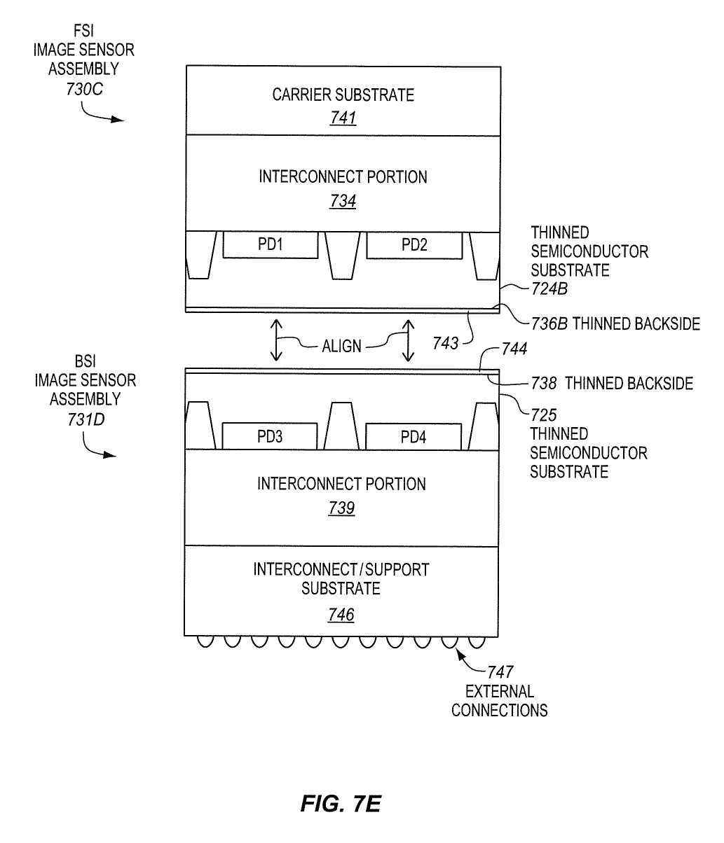

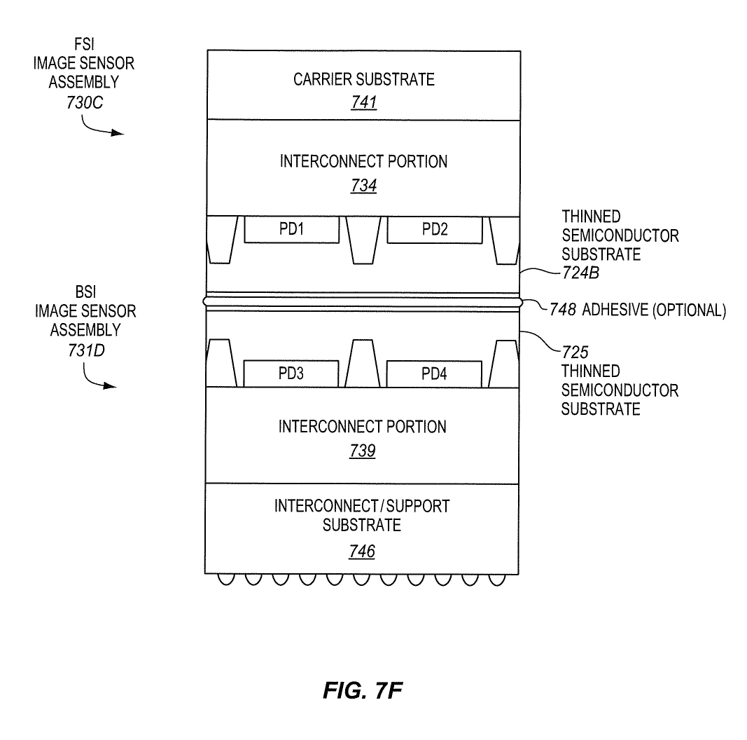

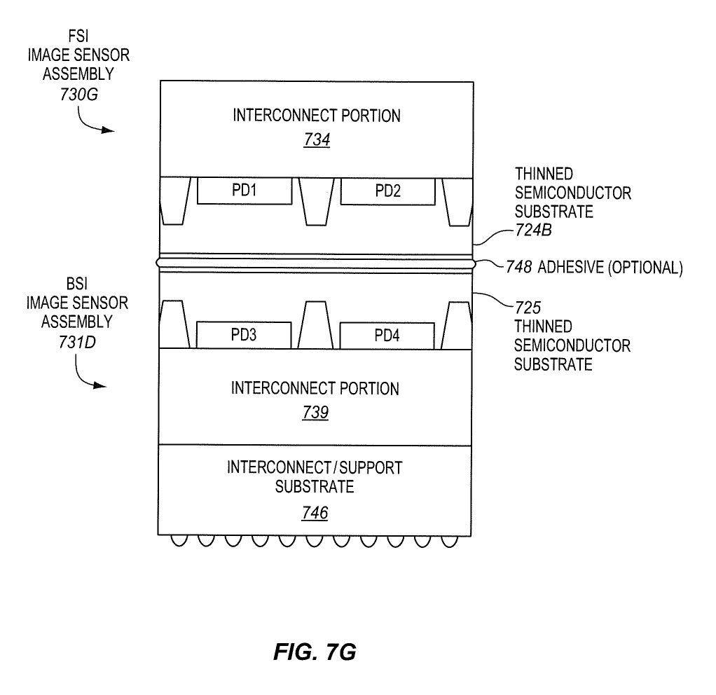

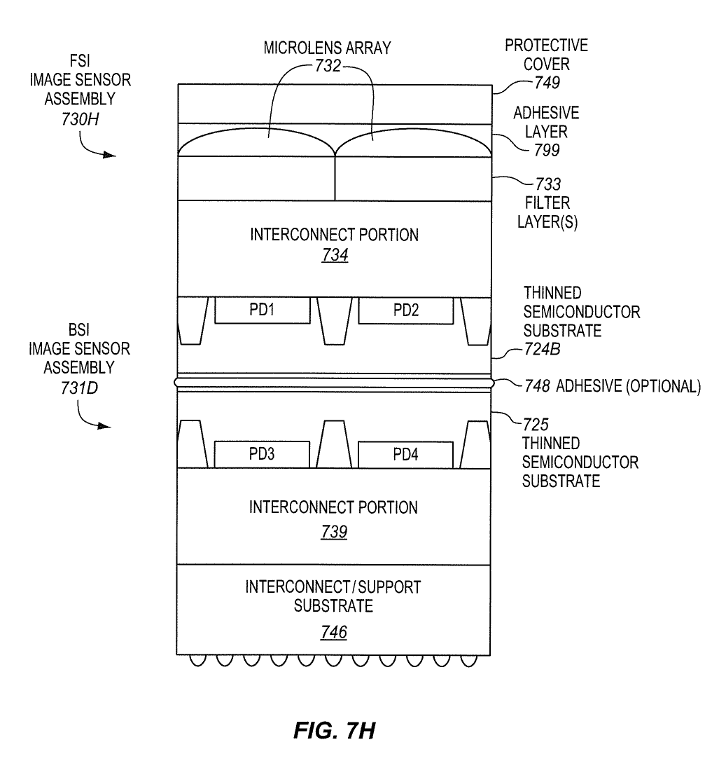

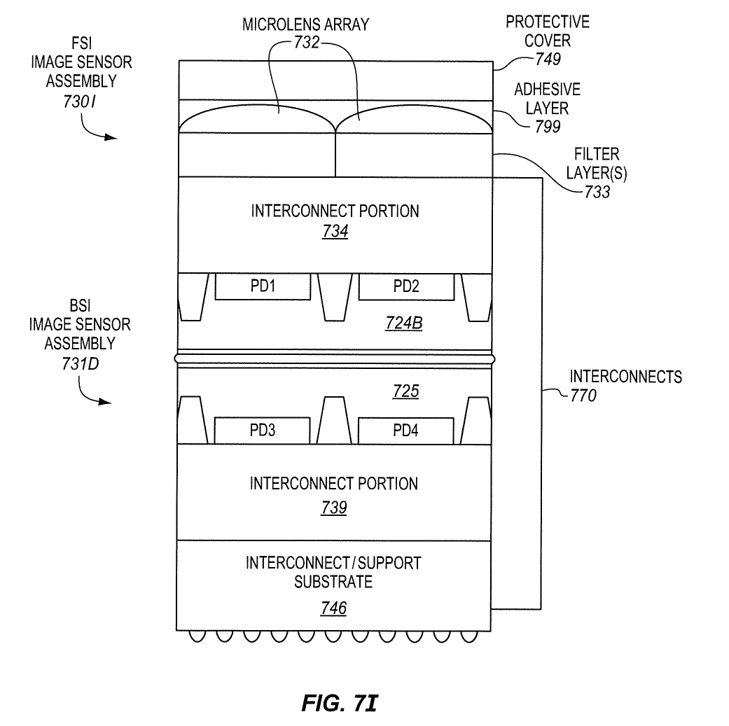

FIGS. 7A-7I are cross-sectional side views of intermediate assemblies representing different stages of an example embodiment of a method of forming an example embodiment of an image sensor that includes an FSI image sensor coupled over a BSI image sensor.

FIG. 7A illustrates optionally applying a carrier wafer or other carrier substrate 741 to a frontside of an example embodiment of an FSI image sensor assembly 730A. By way of example, the carrier substrate may be press bonded to an interconnect portion 734 of the FSI assembly. The carrier substrate may help to provide mechanical support for the FSI image sensor assembly during subsequent thinning and other processing operations. The FSI image sensor assembly may represent a substantially conventional assembly at an intermediate stage of manufacture. The illustrated FSI image sensor assembly includes a semiconductor wafer or other semiconductor substrate 724A having a photodetector array 722 and shallow trench isolation (STI) 740 formed within a frontside portion thereof, and the interconnect portion (e.g., interconnects within a dielectric material) 734 formed over a frontside 739 of the substrate. The illustrated photodetector array includes a first photodetector (PD1) and a second photodetector (PD2). In various aspects, the substantially conventional FSI image sensor assembly may be fabricated, purchased, acquired from another entity, imported, or otherwise provided. As shown, the semiconductor substrate has a first thickness (T1) between the frontside 739 and a backside 736A. In one aspect, the first thickness (T1) may be around 200 μm.

FIG. 7B illustrates thinning the semiconductor substrate 724A of FIG. 7A from the backside 736A to form a thinned semiconductor substrate 724B. During the thinning, the starting first thickness (T1) is reduced to a final second thickness (T2). In various embodiments, the second thickness (T2) may be in the range of between about 1.5 to 10 μm, about 1.5 to 5 μm, or about 1.5 to 3 μm. By way of example, the thinning may be performed by chemical-mechanical polishing (CMP), or other wafer thinning approaches known in the arts. During the thinning operation, the carrier substrate 741 may help to provide mechanical support to the FSI image sensor assembly. Alternatively, if the extent of thinning desired for the particular implementation is not great, or if mechanical damage can be otherwise prevented (e.g., through a carefully performed thinning operation), then the carrier substrate may optionally be omitted. As shown, dangling bonds, lattice mismatches, and/or other surface imperfections 742 may exist on the thinned backside 736B. These surface imperfections may tend to contribute to blooming, dark current, or be otherwise undesirable.

FIG. 7C illustrates optionally passivating the thinned backside 736B of the thinned semiconductor substrate 724B of FIG. 7B. Passivating the thinned backside may include forming a passivation layer 743 on the thinned backside. Passivating the thinned backside may help to remove or at least reduce the number or level of dangling bonds and other surface imperfections 742. By way of example, passivating the thinned backside may include doping the thinned backside, oxidizing the thinned backside, otherwise passivating the thinned backside (e.g., using conventional approaches used to passivate the thinned backsides of BSI image sensors), or a combination thereof.

FIG. 7D illustrates optionally passivating a thinned backside 738 of a thinned semiconductor substrate 725 of an example embodiment of a BSI image sensor assembly 731D. Passivating the thinned backside may include forming a passivation layer 744 on the thinned backside. As before, passivating the thinned backside may help to remove or at least reduce the number or level of dangling bonds and other surface imperfections, which may help to reduce blooming and dark current. By way of example, passivating the thinned backside may include doping the thinned backside, oxidizing the thinned backside, otherwise passivating the thinned backside, or a combination thereof. If desired, an optional anti-reflective layer or coating (not shown) may be applied to the backside surface of the BSI image sensor. In some embodiments, an optional antireflective coating (not shown) may optionally be formed over the passivation layer 744, although this is not required.

The BSI image sensor assembly 731D may represent a substantially conventional assembly at an intermediate stage of manufacture prior to the point of adding microlenses. In various aspects, the BSI image sensor assembly may be fabricated, purchased, acquired from another entity, imported, or otherwise provided. The illustrated BSI image sensor assembly includes a thinned semiconductor wafer or other semiconductor substrate 725 having a photodetector array 723 and STI 745 formed within a frontside portion thereof, and an interconnect portion (e.g., interconnects within a dielectric material) 739 formed over a frontside 737 of the substrate. The illustrated photodetector array includes a third photodetector (PD3) and a fourth photodetector (PD4). As shown, the thinned semiconductor substrate has a third thickness (T3) between the frontside 737 and the thinned backside 738. In one aspect, the third thickness (T3) may be around 1 μm to 30 μm, or around 2 μm to 20 μm, or around 2 μm to 10 μm. The BSI wafer does not necessarily need to be thinned as much as a traditional BSI wafer, since the FSI image sensor instead of the BSI image sensor may detect a lower wavelength fraction of the light.

An optional redistribution layers (RDL) wafer or other interconnect/support substrate 746 is physically and electrically coupled with the interconnect portion. By way of example, the RDL wafer may provide mechanical support and may redistribute the electrical connections from the interconnect portion to external contacts (e.g., a ball grid array) on the back of the RDL wafer. Alternatively, if the thinned semiconductor substrate 725 is sufficiently thick, or the BSI assembly is otherwise sufficiently mechanically strong, then the interconnect/support substrate 746 may optionally be omitted. In such cases, the thinned semiconductor substrate itself may provide a sufficient level of mechanical strength/support.

FIG. 7E illustrates aligning the FSI image sensor assembly 730C of FIG. 7C and the BSI image sensor assembly 731D of FIG. 7D. A thinned backside 736B of the FSI image sensor assembly may oppose/face a thinned backside 738 of the BSI image sensor assembly. Either assembly may be moved and aligned relative to the other. They may be aligned horizontally instead of vertically as shown. Conventional wafer alignment mechanisms may be utilized. The photodetector array of the FSI image sensor assembly may be substantially aligned with respect to (e.g., vertically aligned over) the photodetector array of the BSI image sensor assembly. Corresponding pairs of photodetectors of the FSI and BSI image sensors may be substantially aligned relative to one another (e.g., one over the other). The corresponding pairs of photodetectors of the FSI and BSI image sensors may have substantially the same pitch, density, and layout. In one aspect, wafer aligner equipment may be used to align the substrates. In one particular example, an aligner may use infrared light to image one substrate through the other substrate and align the two substrates. Infrared absorbing alignment marks, or other fiducial marks, may optionally be included on each of the substrates to help better align them. The corresponding photodetectors don't have to be perfectly aligned, but generally should be aligned to within the accuracy of the dimensions of a pixel.

FIG. 7F illustrates bonded, adhered, or otherwise physically coupling the aligned FSI and BSI image sensor assemblies 730C, 731D of FIG. 7E together. The backsides of the FSI and BSI image sensor assemblies may be coupled together. As shown, in some embodiments, an adhesive or other additional material 748 may optionally be included between the FSI and BSI image sensor assemblies in order to hold them together. The additional material may represent an adhesive, glue, glass frit, bonding material, or another organic or inorganic material operable to adhere or couple the assemblies. Other representative examples of suitable approaches for coupling the FSI and BSI image sensor assemblies include, but are not limited to, reactive bonding, thermo-compression bonding, direct wafer bonding, and using other substrate-substrate bonding (e.g., wafer bonding) approaches.

In embodiments that utilize the adhesive or other additional material 748, in some aspects, this adhesive or other additional material may be substantially optically transparent to wavelengths of light that are to be detected by the photodetector array of the BSI image sensor (e.g., one or more of red, near infrared, and infrared lights). In some aspects, the adhesive or other additional material may optionally be substantially filtering to wavelengths of light that are to be detected by the photodetector array of the FSI image sensor (e.g., one or more of blue and green lights). As one example, a material conventionally used for a red filter for a red sensing pixel may optionally be used as the adhesive. A filter material operable to filter out green and blue light may optionally be added to a red light transmitting glue or adhesive material. These are just a few illustrative examples. As another option, the additional material may be confined to regions outside of the regions that light is to traverse to reach the photodetectors.

FIG. 7G illustrates decoupling the carrier substrate 741 from the FSI assembly 730C shown in FIG. 7F. Depending upon the particular way in which the carrier substrate was initially coupled, this decoupling may be performed thermally (e.g., by applying heat), mechanically (e.g., by applying a sliding motion between the carrier substrate and the assembly), or otherwise (e.g., by prying or pealing the carrier substrate from the assembly).

FIG. 7H illustrates forming one or more filter layer(s) 733, an array of microlenses 732, and an optional protective cover (e.g., a coverglass) 749 over the frontside of the FSI image sensor assembly 730C of FIG. 7G to form an FSI image sensor assembly 730H. As will be explained further below, the color filter patterns of the one or more filter layer(s) 733 may be un-conventional but may utilize conventional materials and be formed conventionally. The array of microlenses and the protective cover may be conventional and may be formed as conventional. An adhesive material (e.g., glue) 799 may be used to adhere the coverglass.

FIG. 7I illustrates forming interconnects 770 from the interconnect portion 734 of the FSI image sensor assembly 730H to the interconnect support substrate 746 and/or interconnect portion 739 of the BSI image sensor assembly 731D of FIG. 7I. The interconnects 770 may electrically couple the interconnect portion 734 with the interconnect portion 739 and/or the interconnect support substrate 746. The interconnects 770 may be in a direction orthogonal to a plane of interconnects (e.g., lines, traces, wires, etc.) of the interconnect portion 734. In various example embodiments, interconnects 770 may be formed by through silicon vias (TSV) and/or chip-scale packaging technology. For example, interconnects 770 may be formed by chip-scale wire routing and/or wafer-level chip-scale packaging technology. In one aspect, the interconnects 770 may be formed by wafer-level chip-scale packaging technology adapted from that available from Shellcase Limited, of Jerusalem Israel. Further background information on TSV and chip-scale packaging technology, if desired, is widely available in the public literature, including in U.S. Pat. No. 6,777,767, U.S. Pat. No. 6,040,235, U.S. Pat. No. 6,972,480, and U.S. Pat. No. 6,646,289.

The use of TSV and/or chip-scale packaging technology is not required. In other embodiments, the FSI assembly may be wire bonded to a chip cavity frame, prior to the coverglass being installed, with the BSI assembly under the FSI assembly in a cavity of the chip cavity frame, and the BSI assembly electrical coupled to a lead frame under it through solder balls. This is just one additional example. In still other embodiments, other interconnection approaches may optionally be used (e.g., interconnects may be coupled along the vertical (as shown) edges of the substrates to couple the two substrates, wirebonding may be used to couple the two substrates, or in still other embodiments the electrical signals from the FSI assembly may be taken out from the sides or the top while the electrical signals from the BSI assembly may be taken out from the bottom.)

Embodiments of image sensors that include FSI image sensors coupled over BSI image sensors, so that the FSI image sensors receive input light prior to the BSI image sensors, have been shown and described. However, the scope of the invention is not limited to such image sensors. In other embodiments, a first FSI image sensor or FSI photodetector array may be coupled over a second FSI image sensor or FSI photodetector array. In still other embodiments, a first BSI image sensor or BSI photodetector array may be coupled over a second BSI image sensor or BSI photodetector array. In still further embodiments, a BSI image sensor or BSI photodetector array may be coupled over a FSI image sensor or FSI photodetector array.

In some embodiments, an image sensor as disclosed elsewhere herein may include a color filter array having a repeating color filter pattern. The color filter pattern may include a pattern (e.g., a checkerboard pattern) of light absorbing and/or light transmitting color filters in a fixed or predetermined pattern that may be repeated across the photodetector array. Each color filter of the color filter array may correspond to a corresponding pair of stacked photodetectors (e.g., PD₁ and PD_{M+1} in FIG. 4). That is, light may reach both of the photodetectors of the corresponding pair by passing through the same single filter. In some embodiments, a color filter pattern other than a standard Bayer pattern may be used.

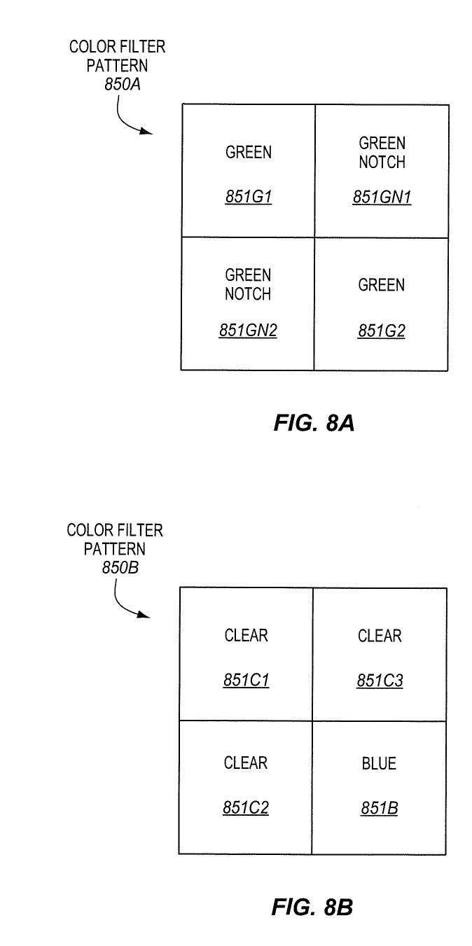

FIG. 8A is a block diagram of a first example embodiment of a suitable color filter pattern 850A. In this example embodiment, the color filter pattern consists essentially of a combination of green filters and green notch filters. As shown, in one aspect, there may be two green filters 851G1, 851G2 and two green notch filters 851GN1, 851GN2. The illustrated arrangement of these filters along the diagonals of the pattern is optional, and other arrangements are also suitable. The green filters may be operable to allow green light to pass through, but may substantially prevent other non-green light from passing through. The green notch filters may be operable to substantially prevent green light from passing through, but may allow other non-green light to pass through. The green notch filters may also be referred to as not green filters.

In operation, green light may be detected by the shallower photodetectors for each of the green filters 851G1, 851G2. Blue light may be detected by the shallower photodetectors for each of the green notch filters 851GN1, 851GN2, as well as red light may be detected by the deeper photodetectors for each of the green notch filters 851GN1, 851GN2. As a result, for the four color filters, two greens, two blues, and two reds may be detected. Advantageously, this color filter pattern in combination with the image sensors disclosed elsewhere herein allows increased color resolution. Rather than just four color signals being detected, which is the case for a conventional Bayer pattern (i.e., two greens, one red, and one blue), six color signals may be detected, namely two reds, two greens, and two blues, for the same four color filters and from within the same lateral area or footprint of the substrate. Advantageously, this may essentially double the red and blue color signals resolution as compared to a conventional Bayer pattern.

FIG. 8B is a block diagram of a second example embodiment of a suitable color filter pattern 850B. In this example embodiment, the color filter pattern consists essentially of a combination of clear filters and blue filters. As shown, in one aspect, there may be three clear filters 851C1, 851C2, 851C3 and one blue filter 851B. The illustrated arrangement of these filters is optional, and other arrangements are also suitable. The blue filter may be operable to allow blue light to pass through, but may substantially prevent other non-blue light from passing through. In some embodiments, the clear filters may be operable to allow all colors of visible light to substantially pass through.

In operation, blue light may be detected by the shallower photodetector for the blue filter 851B. A combination of blue light and green light may be detected by the shallower photodetectors for each of the clear filters 851C1, 851C2, and 851C3. The blue light detected for the blue filter 851B may be subtracted from each of these combinations to obtain three green lights detected by the shallower photodetectors for each of the clear filters 851C1, 851C2, and 851C3. Red light may be detected by each of the deeper photodetectors for each of the clear filters 851C1, 851C2, and 851C3. Accordingly, one blue light, three green lights, and three red lights may be detected. Advantageously, as before, this color filter pattern in combination with the image sensors disclosed elsewhere herein allows increased color resolution. Rather than just four color signals being detected, which is the case for a conventional Bayer pattern (i.e., two greens, one red, and one blue), seven color signals may be detected, namely one blue light, three green lights, and three red lights, for the same four color filters and the same lateral area or footprint of the photodetector array.

Advantageously, the resolution for the red light is essentially tripled, the resolution for the green light is essentially tripled, and the resolution of the blue light is essentially the same. Alternatively, some or all of the color signals for a given color (e.g., some or all of the color signals for blue) may be combined together. This may increase the sensitivity of the image sensor for that color while achieving essentially the same resolution. That is, this embodiment may provide a larger proportion of the same lateral area of the photodetector array collecting the same color as compared to in a conventional image sensor using a Bayer pattern.

Now, an alternate embodiment of the illustrated color filter pattern 850B is contemplated in which some or all of the clear filters 851C1, 851C2, 851C3 may be clear except blue filters that substantially prevent blue light from passing through but allow other portions of the visible spectrum (e.g., green and red light) to pass through. In such an embodiment, the blue light may be filtering out instead of being subtracted out. Such an embodiment again may be useful to provide increased resolution for red and green light and/or increased sensitivity for red and green light.

These are just a few illustrative examples of suitable color filter patterns. Other color filter patterns will be apparent to those skilled in the art and having the benefit of the present disclosure. Another illustrative embodiment may use a standard Bayer pattern and collect all of red, green, and blue in the upper photodetector array, while near infrared or infrared light is collected in the lower photodetector array. The thickness of the photocarrier generation material disposed between the two arrays may be used to adjust the split of wavelengths that are to be detected by the arrays.

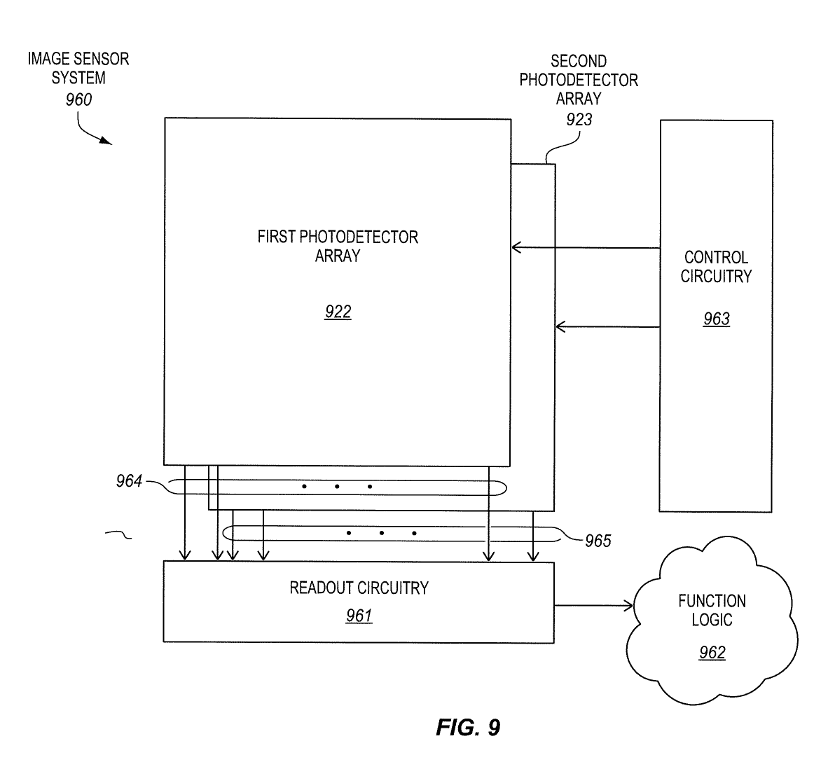

FIG. 9 is a block diagram of an example embodiment of an image sensor system 960. The illustrated embodiment of the image sensor system includes first photodetector array 922, a second photodetector array 923, readout circuitry 961, function logic 962, and control circuitry 963. The photodetector arrays may each include a two-dimensional array of pixels (e.g., each optionally having millions of pixels). The pixels of the image sensor array may be arranged into rows and columns. The photodetector arrays may be either color or black and white and may optionally be used to acquire near infrared or infrared light. The image sensor array may be used to acquire image data (e.g., 2D images and/or video).

During image acquisition, each of the photodetectors or pixels may acquire image data (e.g., an image charge). After each photodetector or pixel has acquired its image data or image charge, the image data may be readout by the readout circuitry 961 and transferred to the function logic 962. The readout circuitry may readout the image data for the first and second photodetector arrays in a coordinated fashion. In various aspects, the image data may be read out with duplicate traditional readout circuits and the streams may be combined off chip, the readouts of the image data for the two arrays may be coordinated on chip and the image data may be combined and interleaved prior to transmission of the image data off chip. Image data may be read out by column readout, serial readout, full parallel readout of all pixels concurrently, etc. A first set of readout lines 964 may be used to readout image data from the first photodetector array and a second set of readout lines 965 may be used to readout image data from the second photodetector array.

In one aspect, the function logic 962 may merely store the image data, or in another aspect the function logic may manipulate the image data using various ways known in the arts (e.g., crop, rotate, remove red eye, adjust brightness, adjust contrast, etc). The function logic may be implemented in hardware, software, firmware, or a combination. The control circuitry 963 is coupled to each of the photodetector arrays to control operational characteristics of the photodetector arrays. For example, the control circuitry may generate a shutter signal for controlling image acquisition. The shutter signal may be a global shutter signal or a rolling shutter signal.

In the description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other. For example, first and second photodetector arrays may be coupled together by one or more intervening materials (e.g., adhesive, photoelectron generation material, etc.)

In the description above, for the purposes of explanation, numerous specific details have been set forth in order to provide a thorough understanding of the embodiments of the invention. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known circuits, structures, devices, and operations have been shown in block diagram form or without detail in order to avoid obscuring the understanding of the description.

It will also be appreciated, by one skilled in the art, that modifications may be made to the embodiments disclosed herein, such as, for example, to the sizes, shapes, configurations, forms, functions, materials, and manner of operation, and assembly and use, of the components of the embodiments. All equivalent relationships to those illustrated in the drawings and described in the specification are encompassed within embodiments of the invention. For simplicity and clarity of illustration, elements illustrated in the figures have not necessarily been drawn to scale. For example, the dimensions of some of the elements are exaggerated relative to other elements for clarity. Further, where considered appropriate, reference numerals, or terminal portions of reference numerals, have been repeated among the figures to indicate corresponding or analogous elements, which may optionally have similar characteristics.

Various operations and methods have been described. Some of the methods have been described in a basic form, but operations may optionally be added to and/or removed from the methods. In addition, while the flow diagrams show a particular order of the operations according to example embodiments, it is to be understood that that particular order is exemplary. Alternate embodiments may optionally perform the operations in different order, combine certain operations, overlap certain operations, etc.

It should also be appreciated that reference throughout this specification to “one embodiment”, “an embodiment”, or “one or more embodiments”, for example, means that a particular feature may be included in the practice of the invention. Similarly, it should be appreciated that in the description various features are sometimes grouped together in a single embodiment, Figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. An image sensor comprising:
a first photodetector array;
a second photodetector array, the second photodetector array coupled under the first photodetector array, wherein photodetectors of the second photodetector array are coupled under corresponding photodetectors of the first photodetector array; and
a thickness of a photocarrier generation material optically coupled between the corresponding photodetectors of the first and second arrays.

2. The image sensor of claim 1, wherein the first photodetector array is formed in a first semiconductor substrate and the second photodetector array is formed in a second semiconductor substrate, and wherein the first and second semiconductor substrates are coupled together.

3. The image sensor of claim 2, wherein the first and second semiconductor substrates are bonded together with at least one of an adhesive, a glue, reactive bonding, thermo-compression bonding, and wafer bonding.

4. The image sensor of claim 1, wherein one of the photodetector arrays is a frontside illuminated (FSI) photodetector array and another is a backside illuminated (BSI) photodetector array.

5. The image sensor of claim 4, wherein the first photodetector array is the FSI photodetector array and the second photodetector array is the BSI photodetector array.

6. The image sensor of claim 1, wherein the second photodetector array is to detect light having a longer wavelength than a wavelength of light that the first photodetector array is to detect.

7. The image sensor of claim 6, wherein the first photodetector array is to detect visible light having wavelengths less than a red light wavelength but not greater than the red light wavelength, and wherein the second photodetector array is to detect light having wavelengths greater than the red light wavelength.

8. The image sensor of claim 6, wherein the first photodetector array is to detect blue light and green light, wherein the second photodetector array is to detect red light but not blue light.

9. The image sensor of claim 6, wherein the first photodetector array is to detect blue light and green light but not near infrared light, and wherein the second photodetector array is to detect the near infrared light but not the blue light or the green light.

10. The image sensor of claim 1, wherein the photocarrier generation material comprises a silicon material, and wherein the thickness of the silicon material between the corresponding photodetectors of the first and second arrays is at least one micrometer.

11. The image sensor of claim 1, further comprising a color filter array having a repeating color filter pattern, wherein the repeating color filter pattern is selected from:
(a) a pattern that consists essentially of green filters and not green filters; and (b) a pattern that consists essentially of clear filters and blue filters.

12. A method comprising:
aligning a first photodetector array and a second photodetector array, wherein aligning the first and second photodetector arrays includes aligning photodetectors of the second photodetector array and corresponding photodetectors of the first photodetector array; and
coupling the aligned first and second photodetector arrays, wherein coupling the aligned first and second photodetector arrays includes optically coupling a thickness of a photocarrier generation material between the aligned corresponding photodetectors of the first and second photodetector arrays.

13. The method of claim 12, wherein aligning the first photodetector array and the second photodetector array comprises aligning a first semiconductor substrate in which the first photodetector array is formed and a second semiconductor substrate in which the second photodetector array is formed.

14. The method of claim 13, wherein coupling the aligned first and second photodetector arrays comprises coupling the aligned first and second semiconductor substrates with at least one of an adhesive, a glue, reactive bonding, thermo-compression bonding, and wafer bonding.

15. The method of claim 12, wherein coupling the aligned first and second photodetector arrays comprises coupling a frontside illuminated (FSI) photodetector array and a backside illuminated (BSI) photodetector array.

16. The method of claim 15, wherein coupling the FSI photodetector array and the BSI photodetector array comprises coupling a backside of a semiconductor substrate in which the FSI photodetector array is disposed with a backside of a semiconductor substrate in which the BSI photodetector array is disposed.

17. The method of claim 15, further comprising thinning a backside surface of the FSI photodetector array.

18. The method of claim 12, wherein optically coupling the thickness of the photocarrier generation material between the aligned corresponding photodetectors of the first and second photodetector arrays comprises optically coupling at least one micrometer of a semiconductor material between the aligned corresponding photodetectors of the first and second photodetector arrays.

19. The method of claim 12, further comprising forming a color filter array having a repeating color filter pattern over the first photodetector array, wherein the repeating color filter pattern is selected from: (a) a pattern that consists essentially of one or more green filters and one or more not green filters; (b) a pattern that consists essentially of one or more clear filters and one or more blue filters; and (c) a pattern that consists essentially of one or more clear except blue filters and one or more blue filters.

20. An image sensor comprising:
a frontside illuminated (FSI) image sensor, the FSI image sensor comprising:
a microlens array that is operable to receive and focus light;
a color filter array optically coupled to receive the focused light from the microlens array and operable to filter the light;
a first interconnect portion optically coupled to receive the light from the color filter array, the first interconnect portion including interconnects disposed within a dielectric material, the dielectric material operable to transmit the light; and
a first die optically coupled to receive the light from the dielectric material, the first die including a first array of photodetectors disposed within a frontside portion of the first die, the first array of photodetectors operable to detect a first portion of the light received by the first die, and the first die including a first thickness of a semiconductor material coupled between the first array of photodetectors and a backside of the first die, the first thickness of the semiconductor material operable to transmit a second portion of the light received by the first die that is not detected by the first array of photodetectors; and
a backside illuminated (BSI) image sensor, the BSI image sensor coupled under the FSI image sensor, the BSI image sensor comprising:
a second die optically coupled to receive the second portion of the light, the second die including a second array of photodetectors disposed within a frontside portion of the second die, and the second die including a second thickness of a semiconductor material coupled between the second array of photodetectors and a backside of the second die, the second thickness of the semiconductor material operable to transmit the second portion of the light, the second array of photodetectors operable to detect the second portion of the light; and
a second interconnect portion coupled with the frontside portion of the second die.

21. The image sensor of claim 20, wherein the color filter array comprises a repeating color filter pattern, and wherein the repeating color filter pattern is selected from: (a) a pattern that consists essentially of one or more green filters and one or more not green filters; (b) a pattern that consists essentially of one or more clear filters and one or more blue filters; and (c) a pattern that consists essentially of one or more clear except blue filters and one or more blue filters.
